(19) United States
(12) Patent Application Publication
(10) Pub. No.: US 2025/0105795 A1
(43) Pub. Date: Mar. 27, 2025

(54) POWER AMPLIFIER

(71) Applicant: Industrial Technology Research Institute, Hsinchu (TW)

(72) Inventors: Jian-Yu Li, Hsinchu City (TW); Tsung Hwa Hsieh, Hsinchu City (TW); Yu-Cheng Hsu, Hsinchu County (TW)

(73) Assignee: Industrial Technology Research Institute, Hsinchu (TW)

(21) Appl. No.: 18/534,748

(22) Filed: Dec. 11, 2023

(30) Foreign Application Priority Data
Sep. 21, 2023 (TW) 112136141

(51) Int. Cl. H03F 1/08; H03F 3/21

(52) U.S. Cl. CPC H03F 1/086; H03F 3/21; H03F 2200/451

(57) ABSTRACT

A power amplifier comprising a first transistor pair and a first odd mode resistor string. The first transistor pair has a first transistor and a second transistor. A first end of the first transistor is symmetrically disposed to a first end of the second transistor. A plurality of first odd mode resistors are serially coupled between the first end of the first transistor and the first end of the second transistor. A total length of the first odd mode resistor string is substantially equal to a distance between the first end of the first transistor and the first end of the second transistor.

### CROSS-REFERENCE TO RELATED APPLICATION

This application claims the priority benefit of Taiwan application no. 112136141, filed on Sep. 21, 2023. The entirety of the above mentioned patent application is hereby incorporated by reference herein and made a part of this specification.

### BACKGROUND

### 1. Technical Field

The present disclosure is related to an amplifier, and more particularly, to a power amplifier.

### 2. Description of Related Art

For radio frequency (RF) circuits, how to eliminate or alleviate characteristic deviation of the circuit is actually one of the most important issues to be resolved in this field.

### SUMMARY

The present disclosure provides a power amplifier that may eliminate or alleviate the offset caused by the metal wires for connecting the odd mode resistors in the odd mode stabilizing circuit.

The power amplifier of the present disclosure includes a first transistor pair and a first odd mode resistor string. The first transistor pair has a first transistor and a second transistor. A first end of the first transistor is symmetrically disposed to a first end of the second transistor. A plurality of first odd mode resistors are serially coupled between the first end of the first transistor and the first end of the second transistor. A total length of the first odd mode resistor string is substantially equal to a distance between the first end of the first transistor and the first end of the second transistor.

Based on the above, the power amplifier of the present disclosure may shorten all or part of the metal wires connected between the odd mode resistor and the transistor or replace it with the odd-mode resistor, thereby effectively avoiding high frequency impacts and offsets of the characteristics of the power amplifier caused by the transmission line effect of the metal wires.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of a power amplifier according to an embodiment of the present disclosure.

FIG. 2A illustrates a schematic diagram of a second odd mode resistor string according to an embodiment of the present disclosure.

FIG. 2B illustrates a schematic diagram of an equivalent circuit of an even-mode excitation of the circuits in FIG. 2A.

FIG. 3 illustrates a comparison diagram of S parameters of the power amplifier according to an embodiment of the present disclosure.

### DESCRIPTION OF THE EMBODIMENTS

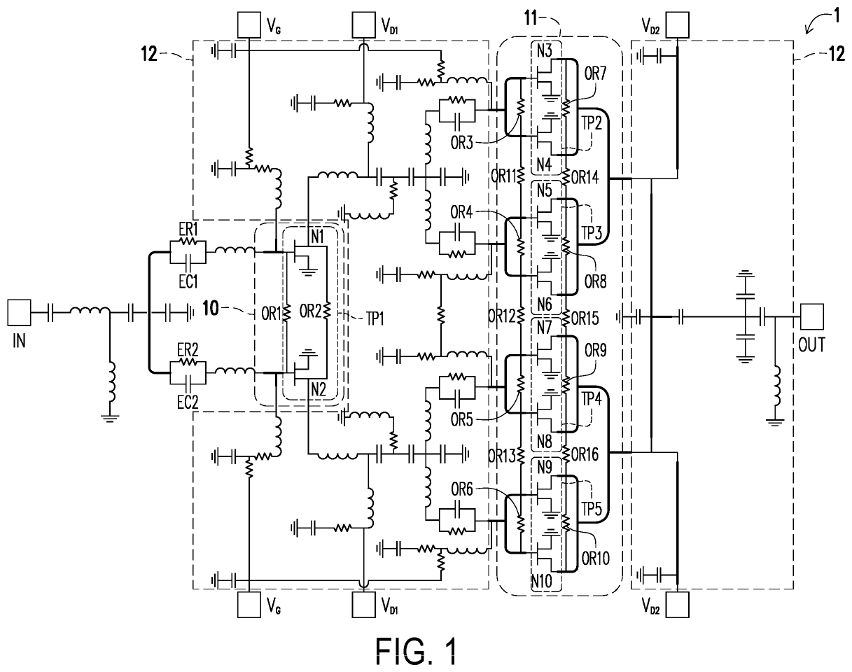

FIG. 1 illustrates a schematic diagram of a power amplifier 1 according to an embodiment of the present disclosure. The power amplifier 1 includes a driver stage circuit 10 and a power stage circuit 11. The driver stage circuit 10 includes a first transistor pair TP1 formed by a first transistor N1 and a second transistor N2. The first transistor N1 is disposed symmetrically to the second transistor N2, so each end of the first transistor N1 and the second transistor N2, including the gate terminal, source terminal and drain terminal, are also disposed in mirror symmetry. The first odd mode resistor string OR1 is coupled between the gate terminals of the first transistor N1 and the second transistor N2. Although not clearly illustrated in FIG. 1, the first odd mode resistor string OR1 actually includes a plurality of first odd mode resistors connected in series, and a total length of these first odd mode resistors coupled together, which is a total length of the first odd mode resistor string OR1, may be substantially equal to a distance between the gate terminals of the first transistor N1 and the second transistor N2. In this way, the connection between the first transistor N1 and the second transistor N2 no longer requires additional connecting wire lines, and may be replaced by the first odd mode resistor string OR1, thereby effectively avoiding unexpected impact brought by the high frequency transmission line effect of the connecting line on the circuit.

Regarding the driver stage circuit 10 of the power amplifier 1, the driver stage circuit 10 further includes a second odd mode resistor string OR2, coupled between the drain terminals of the first transistor N1 and the second transistor N2. Similarly, although not clearly illustrated in FIG. 1, the second odd mode resistor string OR2 actually also includes a plurality of second odd mode resistors connected in series, and a total length of these second odd mode resistors coupled together, which is a total length of the second odd mode resistor string OR2, may be substantially equal to a distance between the drain terminals of the first transistor N1 and the second transistor N2. Therefore, the second odd mode resistor string OR2 may also effectively replace and reduce the connection wiring between the drain terminals of the first transistor N1 and the second transistor N2.

Specifically, the gate terminal of the first transistor N1 receives a signal inputted from an input terminal IN through the parallelly coupled first even mode resistor ER1 and the first even mode capacitor EC1, and the gate terminal of the second transistor N2 also receives the signal inputted from the input terminal IN through the parallelly coupled second even-mode resistor ER2 and the second even-mode capacitor EC2. In addition, the source terminals of the first transistor N1 and the second transistor N2 may be coupled to the reference ground voltage or other components in series and further to the reference ground voltage. In this way, the first transistor N1 and the second transistor N2 included in the first transistor pair TP1 of the driver stage circuit 10 may output the input signal received by the gate terminals to the drain terminal through a common source structure. On the other hand, the first transistor N1 and the second transistor N2 may not only avoid even mode oscillation through the first even mode resistor ER1, the first even mode capacitor EC1, the second even mode resistor ER2 and the second even mode capacitor EC2, but also may avoid odd mode oscillation through the first odd mode resistor string OR1 and the second odd mode resistor string OR2. Since the length of the first odd mode resistor string OR1 is close to or substantially equal to the length between the gate terminals of the first transistor N1 and the second transistor N2, and the length of the second odd mode resistor string OR2 is close to or substantially equal to the length between the drain terminals of the second odd mode resistor string OR2, the first odd mode resistor string OR1 and the second odd mode resistor string OR2 may effectively reduce the length of the metal wires between the first transistor N1 and the second transistor N2, thereby avoiding the high frequency transmission line effect caused by the metal traces therebetween.

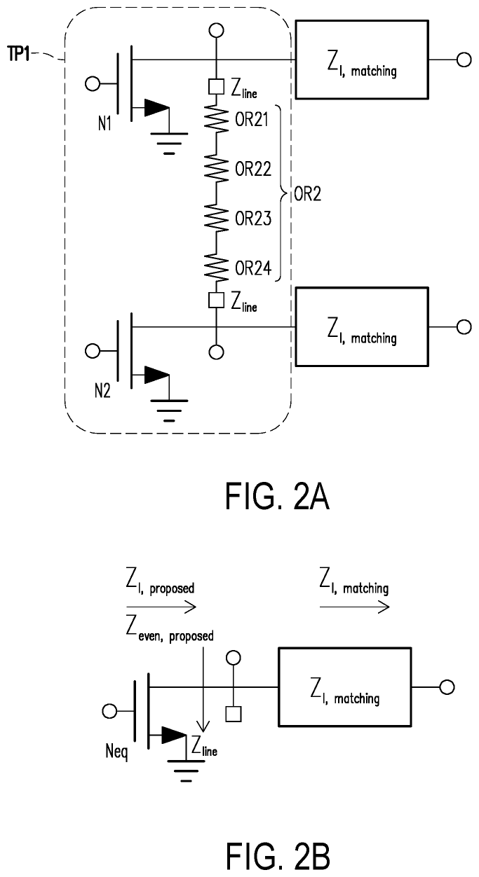

FIG. 2A illustrates a schematic diagram of a second odd mode resistor string OR2 according to an embodiment of the present disclosure. As shown in FIG. 2A, the second odd mode resistor string OR2 is coupled between the drain terminals of the first transistor N1 and the second transistor N2. The second odd mode resistor string OR2 may be formed by a plurality of second odd mode resistors OR21-OR24 connected in series between the drain terminals of the first transistor N1 and the second transistor N2. In addition, there is a metal wire with a characteristic impedance Zₗᵢₙₑ between the drain terminals of the first transistor N1 and the second transistor N2, together coupled in series with the second odd-mode resistors OR21˜OR24 between the drain terminals of the first transistor N1 and the second transistor N2. Particularly, the second odd mode resistor string OR2 is disposed for eliminating the odd mode oscillation generated on the drain terminals of the first transistor N1 and the second transistor N2. As shown in FIG. 2A, if the metal wire with the characteristic impedance of Zₗᵢₙₑ is not taken into consideration as a part of the impedance matching circuit, the load impedance Z_{l,matching} will be affected, causing and characteristic deviations of the circuit.

FIG. 2B illustrates a schematic diagram of an equivalent circuit of an even-mode excitation of the circuits in FIG. 2A. As shown in FIG. 2B, the first transistor pair TP1 in FIG. 2A may be equivalent to the transistor Neq in FIG. 2B. The impedance seen by the drain terminal of the transistor Neq satisfies the following relationship,

Z_{l,proposed}=Z_{even,proposed}||Z_{l,matching}

where Z_{l, proposed} is an equivalent impedance on the drain terminal of transistor Neq, Z_{even, proposed} is an impedance between the drain terminals of the first transistor N1 and the second transistor N2 at even mode excitation, Z_{l,matching} is an impedance of the matching circuit. In order to prevent the impedance between the drain terminals of the first transistor N1 and the second transistor N2 from affecting the impedance of the matching circuit, the resistance of Z_{even, proposed} is generally the larger the better. In addition, according to the transmission line formula, Z_{even, proposed} can be expressed by the following equation,

Z_{even,proposed}=−jZₗᵢₙₑ cotθ

where Zₗᵢₙₑ is the characteristic impedance of the metal wire. Particularly, by shortening the length of the metal wire between the first transistor N1 and the second transistor N2, the angle θ in the above equation can be approximate to zero, thereby making Z_{even, proposed} resistance approximated to infinity. In other words, at even mode excitation, the impedance between the drain terminals of the first transistor N1 and the second transistor N2 is approximated to cutoff, so that the impedance of the matching circuit will no longer be affected by the transmission line effect brough by the metal wire. Thus, the power amplifier 1 may be operated in ideal conditions.

In some embodiments, the first odd mode resistor string OR1 and the second odd mode resistor string OR2 may be divided into a plurality of first odd mode resistors and second odd mode resistors connected in series with any number or resistance value. Although it is illustrated in FIG. 2A that the second odd mode resistor string OR2 is divided into four second odd mode resistors OR21-OR24 coupled in series, but other numbers of second odd mode resistors fall within the scope of various embodiments of the second odd mode resistor string OR2. In addition, the resistance values of the second odd-mode resistors OR21-OR24 may be the same or different, as long as the total length of the second odd-mode resistors OR21-OR24 coupled in series may be close to or substantially equal to the distance between the drain terminals of the first transistor N1 and the second transistor N2. In this way, the second odd-mode resistors OR21˜OR24 may minimize the length of the metal wire between the drain terminals of the first transistor N1 and the second transistor N2, or even completely replace the metal wire between the drain terminals of the first transistor N1 and the second transistor N2, providing an ideal operating environment for the first transistor pair TP1.

In some embodiments, only one of the first odd mode resistor string OR1 and the second odd mode resistor string OR2 may be disposed in the first transistor pair TP1. Although it is illustrated in FIG. 1 that the first odd mode resistor string OR1 is disposed between the gate terminals of the first transistor pair TP1 and the second odd mode resistor string OR2 is disposed between the drain terminals of the first transistor pair TP1, in some embodiments, only one of the first odd mode resistor string OR1 and the second odd mode resistor string OR2 may be disposed in the first transistor pair TP1 of the power amplifier 1. Both of the power amplifier that only disposed with the first odd mode resistor string OR1 or the second odd mode resistor string OR2 should both all fall within the scope of various embodiments of the power amplifier 1.

Regarding the power stage circuit 11 of the power amplifier 1, please refer to FIG. 1 again. The power stage circuit 11 is coupled to the driver stage circuit 10. The power stage circuit 11 includes a plurality of transistor pairs TP2-TP5 and a plurality of odd mode resistor strings. The transistor pairs TP2-TP5 of the stage circuit 11 are all coupled to the drain terminal of the first transistor pair TP1. The odd mode resistor strings OR3-OR16 of the power stage circuit 11 are coupled between the gate terminals or the drain terminals of the transistors in the power stage circuit 11. Specifically, the odd mode resistor strings OR3-OR10 are respectively disposed internally of the corresponding transistor pair TP2-TP5, and more particularly, they are coupled between the gate terminals or the drain terminals of two transistors from one same transistor pair TP2-TP5. The odd mode resistor string OR11-OR16 are coupled externally of the corresponding transistor pair TP2-TP5, and more particularly, they are coupled between the gate terminals or the drain terminals of two transistors from different transistor pairs TP2-TP5.

Regarding the transistor pairs TP2-TP5, the second transistor pair TP2 includes a third transistor N3 and a fourth transistor N4. The gate terminals of the third transistor N3 and the fourth transistor N4 are coupled to the drain terminal of the first transistor N1. The drain terminal of third transistor N3 is coupled to the drain terminal of the fourth transistor N4. The source terminals of the third transistor N3 and the fourth transistor N4 receive the reference ground voltage. The third transistor pair TP3 includes a fifth transistor N5 and a sixth transistor N6. The gate terminals of fifth transistor N5 and the sixth transistor N6 are coupled to the drain terminal of the first transistor N1. The drain terminal of the fifth transistor N5 is coupled to the drain terminal of the sixth transistor N6. The source terminals of the fifth transistor N5 and the sixth transistor N6 receive the reference ground voltage. The fourth transistor pair TP4 includes a seventh transistor N7 and an eighth transistor N8. The gate terminals of the seventh transistor N7 and the eighth transistor N8 are coupled to the drain terminal of the second transistor N2. The drain terminal of the seventh transistor N7 is coupled to the drain terminal of the eighth transistor N8. The source terminals of the seventh transistor N7 and the eighth transistor N8 receive the reference ground voltage. The fifth transistor pair TP5 includes a ninth transistor N9 and a tenth transistor N10. The gate terminals of the ninth transistor N9 and the tenth transistor N10 are coupled to the drain terminal of the second transistor N2. The drain terminal of the ninth transistor N9 is coupled to the drain terminal of the tenth transistor N10. The source terminals of the ninth transistor N9 and the tenth transistor N10 receive the reference ground voltage. The drain terminals of the second transistor pair TP2, the third transistor pair TP3, the fourth transistor TP4 pair, and the fifth transistor pair TP5 are coupled together to the output terminal OUT.

Regarding the odd mode resistor strings OR3-OR10, the odd mode resistor strings OR3-OR10 are respectively coupled between the two transistors internally of corresponding one of the transistor pair TP2-TP5. Specifically, the third odd mode resistor string OR3 is coupled between the gate terminals of the second transistor pair TP2. A total length of the third odd mode resistor string OR3 is substantially equal to a distance between the gate terminals of the second transistor pair TP2. The fourth odd mode resistor string OR4 is coupled between the gate terminals of the third transistor pair TP3. A total length of the fourth odd mode resistor string OR4 is substantially equal to a distance between the gate terminals of third transistor pair TP3. The fifth odd mode resistor string OR5 is coupled between the gate terminals of the fourth transistor pair TP4. A total length of the fifth odd mode resistor string OR5 is substantially equal to a distance between the gate terminals of the fourth transistor pair TP4. The sixth odd mode resistor string OR6 is coupled between the gate terminals of the fifth transistor pair TP5. A total length of the sixth odd mode resistor string OR6 is substantially equal to a distance between the gate terminals of the fifth transistor pair TP5.

The seventh odd mode resistor string OR7 is coupled between the drain terminals of the second transistor pair TP2. A total length of the seventh odd mode resistor string OR7 is substantially equal to a distance between the drain terminals of the second transistor pair TP2. The eighth odd mode resistor string OR8 is coupled between the drain terminals of the third transistor pair TP3. A total length of the eighth odd mode resistor string OR8 is substantially equal to a distance between the drain terminals of the third transistor pair TP3. The ninth odd mode resistor string OR9 is coupled between the drain terminals of the fourth transistor pair TP4. A total length of the ninth odd mode resistor string OR9 is substantially equal to a distance between the drain terminal of the fourth transistor pair TP4. The tenth odd mode resistor string OR10 is coupled to the drain terminal of the fifth transistor pair TP5. A total length of the tenth odd mode resistor string TP10 is substantially equal to a distance between the drain terminals of the fifth transistor pair TP5.

Regarding the odd mode resistor strings OR11-OR16, the odd mode resistor string OR11-OR16 are coupled between the gate terminal or the drain terminals of two transistors from different transistor pairs TP2-TP5. Specifically, the eleventh odd mode resistor string OR11 is coupled between the gate terminal of the fourth transistor N4 of the second transistor pair TP2 and the gate terminal of the fifth transistor N5 of the third transistor pair TP3. A total length of the eleventh odd mode resistor string OR11 is substantially equal to a distance between the gate terminals of the fourth transistor N4 and the fifth transistor N5. The twelfth odd mode resistor string OR12 is coupled between the gate terminal of the sixth transistor N6 of the third transistor pair TP3 and the gate terminal of the seventh transistor N7 of the fourth transistor pair TP4. A total length of the twelfth odd mode resistor string OR12 is substantially equal to a distance between the gate terminals of the sixth transistor N6 and the seventh transistor N7. The thirteenth odd mode resistor string OR13 is coupled between the gate terminal of the eighth transistor N8 of the fourth transistor pair TP4 and the gate terminal of the ninth transistor N9 of the fifth transistor pair TP5. A total length of the thirteenth odd mode resistor string OR13 is substantially equal to a distance between the gate terminals of the transistor N8 and the ninth transistor N9. The fourteenth odd mode resistor string OR14 is coupled between the drain terminal of the fourth transistor N4 of the second transistor pair TP2 and the drain terminal of the fifth transistor N5 of the third transistor pair TP3. A total length of the fourteenth odd mode resistor string OR14 is substantially equal to a distance between the drain terminals of the fourth transistor N4 and fifth transistor N5. The fifteenth odd mode resistor string OR15 is coupled to the drain terminal of sixth transistor N6 of the third transistor pair TP3 and the drain terminal of the seventh transistor N7 of the fourth transistor pair TP4. A total length of the fifteenth odd mode resistor string OR15 is substantially equal to a distance between the drain terminals of the sixth transistor N6 and the seventh transistor N7. The sixteenth odd mode resistor string OR16 is coupled between the drain terminal of the eighth transistor N8 of the fourth transistor pair TP4 and the drain terminal of the ninth transistor N9 of the fifth transistor pair TP5. A total length of the sixteenth odd mode resistor string OR16 is substantially equal to a distance between the drain terminals of the eighth transistor N8 and the ninth transistor N9.

In this way, the odd mode resistor strings OR3-OR16 may be respectively divided into a plurality of serially connected odd mode resistors, so that the metal wires provided between the transistors may be effectively reduced or even completely replaced by the mode resistor strings OR3-OR16, thereby providing an ideal operating environment for the first transistor pair TP1 and effectively eliminating the transmission line effect caused by the metal wires.

In other aspect, the power amplifier 1 also includes a connection circuit 12. The connection circuit 12 is formed by capacitors, inductors, and resistors, to bias and decouple through connections of these passive components. Specifically, the circuit 12 may provide the bias voltages V_{G}, V_{D1}, and V_{D2} to appropriate nodes after biasing, and provide the output signal generated by the driver stage circuit 10 to the input terminal of the power stage circuit 11, which is the gate terminals of the second transistor pair TP2 to the fifth transistor pair TP5, after decouple. Therefore, proper biased voltages and the connection relationship of the power amplifier 1 may be provided.

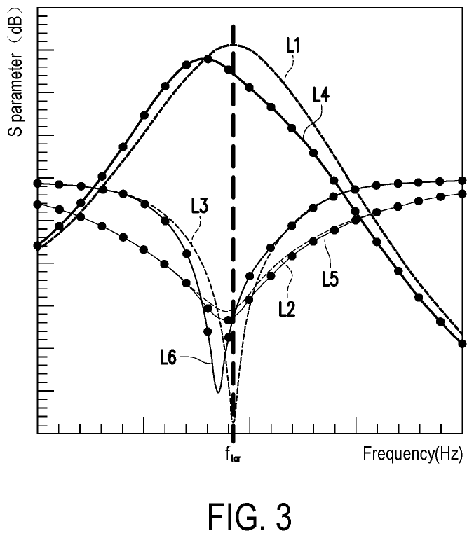

FIG. 3 illustrates a comparison diagram of S parameters of the power amplifier 1 according to an embodiment of the present disclosure. In FIG. 3, lines L1-L6 are illustrated, where the lines L1-L3 are S21, S11, S22 parameters of the power amplifier 1 in FIG. 1, and the lines L4-L6 are S21, S11, S22 parameters of another power amplifier with the same circuit structure. However, the power amplifier corresponding to the lines L4-L6 uses metal wires for connections between the odd mode resistor and the transistor. The parameter S11 is, for example, a reflection coefficient of a signal fed to an input terminal and measured at the input terminal of the circuit. The parameter S21 is, for example, an amplification coefficient of the signal fed to the input terminal and measured at an output terminal of the circuit. The parameter S22 is, for example, a reflection coefficient of the signal fed to the output terminal and measured at the output terminal of the circuit.

Specifically, the power amplifier 1 corresponding to the lines L1-L3 and another power amplifier corresponding to the lines L4-L6 are both designed to operate at the target frequency fₜₐᵣ. As shown in FIG. 3, since the metal wires used to connect the odd-mode resistors and the transistor are shortened to a minimum or completely replaced by the odd-mode resistors, the transmission line effect of the metal wires can be effectively avoided, rendering peaks of the lines L1-L3 and the target frequency fₜₐᵣ aligned. In comparison, for another power amplifier, if the metal wire for connection is not taken into consideration as part of the impedance matching circuit in advance, the peaks of the line L4-L6 will be deviated from the target frequency fₜₐᵣ due to the transmission line effect of the metal wires.

In summary, the present disclosure realizes the resistors used to suppress odd-mode oscillations in the power amplifier with the plurality of odd-mode resistors coupled in series, so that a total length of the odd-mode resistors coupled in series may be substantially equal to a distance between the endpoints of the two transistors to be connected. Therefore, the length of the metal wire used to connect the transistor and the odd-mode resistor in the power amplifier can be effectively shortened or even completely replaced, thereby effectively eliminating the transmission line effect caused by the metal wire in the power amplifier.

As used herein, the terms “substantially,” “substantial,” “approximately,” and “about” are used to denote and account for small variations. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, a thickness of a film or a layer being “substantially uniform” can refer to a standard deviation of less than or equal to ±10% of an average thickness of the film or the layer, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within 50 μm of lying along a same plane, such as within 40 within 30 within 20 within 10 or within 1 μm of lying along the same plane. Two components can be deemed to be “substantially aligned” if, for example, the two components overlap or are within 200 within 150 within 100 within 50 within 40 within 30 within 20 within 10 or within 1 μm of overlapping. Two surfaces or components can be deemed to be “substantially perpendicular” if an angle therebetween is, for example, 90°±10°, such as ±5°, ±4°, ±3°, ±2°, ±1°, ±0.5°, ±0.1°, or ±0.05°. When used in conjunction with an event or circumstance, the terms “substantially,” “substantial,” “approximately,” and “about” can refer to instances in which the event or circumstance occurs precisely, as well as instances in which the event or circumstance occurs to a close approximation.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A power amplifier, comprising:
a first transistor pair, having a first transistor and a second transistor, a first end of the first transistor symmetrically disposed to a first end of the second transistor; and
a first odd mode resistor string, a plurality of first odd mode resistors of the first odd mode resistor string are coupled in series between the first end of the first transistor and the first end of the second transistor, a total length of the first odd mode resistor string being substantially equal to a distance between the first end of the first transistor and the first end of the second transistor.

2. The power amplifier of claim 1, wherein a second end of the first transistor symmetrically disposed to a second end of the second transistor being, the power amplifier further comprising:
a second odd mode resistor string, a plurality of second odd mode resistors of the second odd mode resistor string coupled in series between a second of the first transistor and a second end of the second transistor, a total length of the second odd mode resistor string is substantially equal to a distance between the second end of the first transistor and the second end of the second transistor.

3. The power amplifier of claim 1, wherein the first ends of the first transistor and the second transistor are both drain terminals, or the first ends of the first transistor and the second transistor are both gate terminals.

4. The power amplifier of claim 1, wherein the first ends of the first transistor and the second transistor are both gate terminals, the power amplifier further comprises:
a first even mode resistor, coupled between an input terminal and the first end of the first transistor;
a first even mode capacitor, coupled in parallel to the first even mode resistor;
a second even mode resistor, coupled between the input terminal and the first end of the second transistor; and
a second even mode capacitor, coupled in parallel to the second even mode resistor.

5. The power amplifier of claim 1, wherein the power amplifier comprises:
a driver stage circuit, comprising the first transistor pair and the first odd mode resistor string; and
a power stage circuit, coupled to the driver stage circuit, the power stage circuit comprising:
a plurality of transistor pairs, coupled to a second end of the first transistor pair; and
a plurality of odd mode resistor strings, respectively coupled between first ends of the corresponding transistor pairs, wherein a total length of each odd mode resistor string is substantially equal to a distance between the first ends of the corresponding transistor pairs.

6. The power amplifier of claim 5, wherein the plurality of transistor pairs comprise:
a second transistor pair, comprising a third transistor and a fourth transistor, gate terminals of the third transistor and the fourth transistor being coupled to a drain terminal of the first transistor, a drain terminal of the third transistor being coupled to a drain terminal of the fourth transistor, source terminals of the third transistor and the fourth transistor receive a reference ground voltage;
a third transistor pair, comprising a fifth transistor and a sixth transistor, gate terminals of the fifth transistor and the sixth transistor being coupled to a drain terminal of the first transistor, a drain terminal of the fifth transistor being coupled to a drain terminal of the sixth transistor, source terminals of the fifth transistor and the sixth transistor receive the reference ground voltage;
a fourth transistor pair, comprising a seventh transistor and an eighth transistor, gate terminals of the seventh transistor and the eighth transistor being coupled to a drain terminal of the second transistor, a drain terminal of the seventh transistor being coupled to a drain terminal of the eighth transistor, source terminals of the seventh transistor and the eighth transistor receive the reference ground voltage; and
a fifth transistor pair, comprising a ninth transistor and a tenth transistor, gate terminals of the ninth transistor and the tenth transistor being coupled to the drain terminal of the second transistor, a drain terminal of the ninth transistor being coupled to a drain terminal of the tenth transistor, source terminals of the ninth transistor and the tenth transistor receive the reference ground voltage,
wherein the drain terminals of the second transistor pair, the third transistor pair, the fourth transistor pair, and the fifth transistor pair are together coupled to an output terminal.

7. The power amplifier of claim 5, wherein the plurality of odd mode resistor strings comprise:
a third odd mode resistor string, coupled between the gate terminals of the second transistor pair, a total length of the third odd mode resistor strings being substantially equal to a distance between the gate terminals of the second transistor pair;
a fourth odd mode resistor string, coupled between the gate terminal of the third transistor pair, a total length of the fourth odd mode resistor string being substantially equal to a distance between the gate terminals of the third transistor pair;
a fifth odd mode resistor string, coupled between the gate terminals of the fourth transistor pair, a total length of the fifth odd mode resistor string being substantially equal to a distance between the gate terminals of the fourth transistor pair;
a sixth odd mode resistor string, coupled between the gate terminals of the fifth transistor pair, a total length of the sixth odd mode resistor string being substantially equal to a distance between the gate terminals of the fifth transistor pair.

8. The power amplifier of claim 5, wherein the plurality of odd mode resistor strings comprise:
a seventh odd mode resistor string, coupled between the drain terminals of the second transistor pair, a total length of the seventh odd mode resistor string being substantially equal to a distance between the drain terminals of the second transistor pair;
an eighth odd mode resistor string, coupled between the drain terminals of the third transistor pair, a total length of the eighth odd mode resistor string being substantially equal to a distance between the drain terminals of the third transistor pair;
a ninth odd mode resistor string, coupled between the drain terminals of the fourth transistor pair, a total length of the ninth odd mode resistor string being substantially equal to a distance between the drain terminals of the fourth transistor pair; and
a tenth odd mode resistor string, coupled between the drain terminals of the fifth transistor pair, a total length of the tenth odd mode resistor string being substantially equal to a distance between the drain terminals of the fifth transistor pair.

9. The power amplifier of claim 5, wherein the plurality of odd mode resistor strings comprise:
an eleventh odd mode resistor string, coupled between the gate terminal of the fourth transistor of the second transistor pair and the gate terminal of the fifth transistor of the third transistor pair, a total length of the eleventh odd mode resistor string being substantially equal to a distance between the gate terminals of the fourth transistor and the fifth transistor;
a twelfth odd mode resistor string, coupled between the gate terminal of the sixth transistor of the third transistor pair and the gate terminal of the seventh transistor and the fourth transistor pair, a total length of the twelfth odd mode resistor string being substantially equal to a distance between the gate terminals of the sixth transistor and the seventh transistor; and
a thirteenth odd mode resistor string, coupled between the gate terminal of the eighth transistor and the fourth transistor pair and the gate terminal of the ninth transistor of the fifth transistor pair, a total length of the thirteenth odd mode resistor string being substantially equal to a distance between the gate terminals of the eighth transistor and the ninth transistor.

10. The power amplifier of claim 5, wherein the plurality of odd mode resistor strings comprise:
a fourteenth odd mode resistor string, coupled between the drain terminal of the fourth transistor of the second transistor pair and the drain terminal of the fifth transistor of the third transistor pair, a total distance of the fourteenth odd mode resistor string being substantially equal to a distance between the drain terminals of the fourth transistor and the fifth transistor;
a fifteenth odd mode resistor string, coupled between the drain terminal of the sixth transistor of the third transistor pair and the drain terminal of the seventh transistor of the fourth transistor pair, a total length of the fifteenth odd mode resistor string being substantially equal to a distance between the drain terminals of the sixth transistor and the seventh transistor; and
a sixteenth odd mode resistor string, coupled between the drain terminal of the eighth transistor of the fourth transistor pair and the drain terminal of the ninth transistor of the fifth transistor pair, a total length of the sixteenth odd mode resistor string being substantially equal to a distance between the drain terminals of the eighth transistor and the ninth transistor.
